(19) United States
(12) Patent Application Publication
(10) Pub. No.: US 2025/0046686 A1
(43) Pub. Date: Feb. 6, 2025

(54) CAPACITIVE COUPLING PACKAGE STRUCTURE

(71) Applicants: LITE-ON SINGAPORE PTE. LTD., Singapore (SG); LITE-ON TECHNOLOGY CORPORATION, TAIPEI CITY (TW)

(72) Inventors: YOU-FA WANG, SINGAPORE (SG); CHUN-FATT CHAN, Singapore (SG); TING-WEI KAO, New Taipei City (TW); GUANG-LI SONG, SINGAPORE (SG)

(21) Appl. No.: 18/919,577

(22) Filed: Oct. 18, 2024

Related U.S. Application Data
(63) Continuation-in-part of application No. 18/648,672, filed on Apr. 29, 2024.

(30) Foreign Application Priority Data
May 19, 2023 (CN) 202310567649.0
Oct. 20, 2023 (SG) 10202302974Q
Sep. 25, 2024 (CN) 202422334283.5

(51) Int. Cl. H01L 23/495; H01L 23/00; H01L 23/31; H01L 25/065

(52) U.S. Cl. CPC H01L 23/49575; H01L 23/3135; H01L 23/49589; H01L 25/0655; H01L 24/48; H01L 2224/48245

(57) ABSTRACT

A capacitive coupling package structure includes a first package member, a second package member, a first conductive component, a second conductive component, a first chip, and a second chip. The first package member has two first sides and two second sides that are opposite and connected to the two first sides. The first package member is covered by the second package member. The first conductive component and the second conductive component are disposed in the first package member. Portions of the first conductive component and the second conductive component extend through the two first sides to the outside of the second package member. Other portions of the first conductive component and the second conductive component are flush with the two second sides. The first chip and the second chip establish a capacitive coupling relationship through the first conductive component and the second conductive component.

### CROSS-REFERENCE TO RELATED PATENT APPLICATION

This application claims the benefit of priorities to China Patent Application No. 202310567649.0, filed on May 19, 2023, in the People's Republic of China, China Patent Application No. 202422334283.5, filed on Sep. 25, 2024, in the People's Republic of China, and the Singapore Provisional Patent Application Ser. No. 10202302974Q, filed on Oct. 20, 2023. The entire content of the above identified applications is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a package structure, and more particularly to a capacitive coupling package structure.

### BACKGROUND OF THE DISCLOSURE

A conventional capacitive coupling package structure, during the manufacturing process, mostly encapsulates the chip and conductive components in a single-mode packaging method. However, the conventional capacitive coupling package structure is based on the use of single-mode packaging, which can result in unsatisfactory performance in isolation voltage of the conventional capacitive coupling package structure.

### SUMMARY OF THE DISCLOSURE

In response to the above-referenced technical inadequacy, the present disclosure provides a capacitive coupling package structure.

In order to solve the above-mentioned problems, one of the technical aspects adopted by the present disclosure is to provide a capacitive coupling package structure. The capacitive coupling package structure includes a first package member, a second package member, a first conductive component, a second conductive component, a first chip, and a second chip. The first package member has two first sides and two second sides that are opposite to the two first sides and that are connected to the two first sides. The first package member is covered by the second package member. The first conductive component and the second conductive component are disposed in the first package member. A portion of the first conductive component and a portion of the second conductive component respectively extend through the two first sides of the first package member to the outside of the second package member. Another portion of the first conductive component and another portion of the second conductive component are flush with the two second sides. The first chip is electrically coupled to the first conductive component, and the second chip is electrically coupled to the second conductive component. A capacitive coupling relationship is established by the first chip and the second chip through the first conductive component and the second conductive component.

Therefore, in the capacitive coupling package structure provided by the present disclosure, by virtue of “the first conductive component and the second conductive component being disposed in the first package member,” and “a portion of the first conductive component and a portion of the second conductive component respectively extending through the two first sides to the outside of the second package member, and another portion of the first conductive component and another portion of the second conductive component being flush with the two second sides,” the capacitive coupling package structure can increase the isolation voltage.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view of a capacitive coupling package structure according to one embodiment of the present disclosure;

FIG. 2 is a schematic view of a capacitive coupling package structure according to one embodiment of the present disclosure;

FIG. 3 is a schematic view of a capacitive coupling package structure according to one embodiment of the present disclosure;

FIG. 4 is a schematic view of a capacitive coupling package structure according to one embodiment of the present disclosure;

FIG. 5 to FIG. 9 are schematic side views of a capacitive coupling package structure according to one embodiment of the present disclosure;

FIG. 10 is a schematic view of a capacitive coupling package structure according to one embodiment of the present disclosure;

FIG. 11 is a schematic view of a capacitive coupling package structure according to one embodiment of the present disclosure;

FIG. 12 is a schematic view of a capacitive coupling package structure according to one embodiment of the present disclosure;

FIG. 13 to FIG. 15 are schematic side views of a capacitive coupling package structure according to one embodiment of the present disclosure; and

FIG. 16 to FIG. 18 are flowcharts of a manufacturing method for a capacitive coupling package structure according to one embodiment of the present disclosure;

FIG. 19 is a schematic perspective view of the capacitive coupling package structure according to the present disclosure in another implementation.

FIG. 20 is a schematic top view of FIG. 19;

FIG. 21 is a schematic perspective view showing the first conductive component and the second conductive component being covered by the first package member according to the present disclosure;

FIG. 22 is a schematic cross-sectional view taken along line XXII-XXII of FIG. 21;

FIG. 23 is another schematic top view of FIG. 19;

FIG. 24 is a schematic cross-sectional view of FIG. 23;

FIG. 25 is yet another schematic top view of FIG. 19;

FIG. 26 is a schematic enlarged view of section XXVI of FIG. 25; and

FIG. 27 is a schematic perspective view of the capacitive coupling package structure of FIG. 19 in another implementation.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

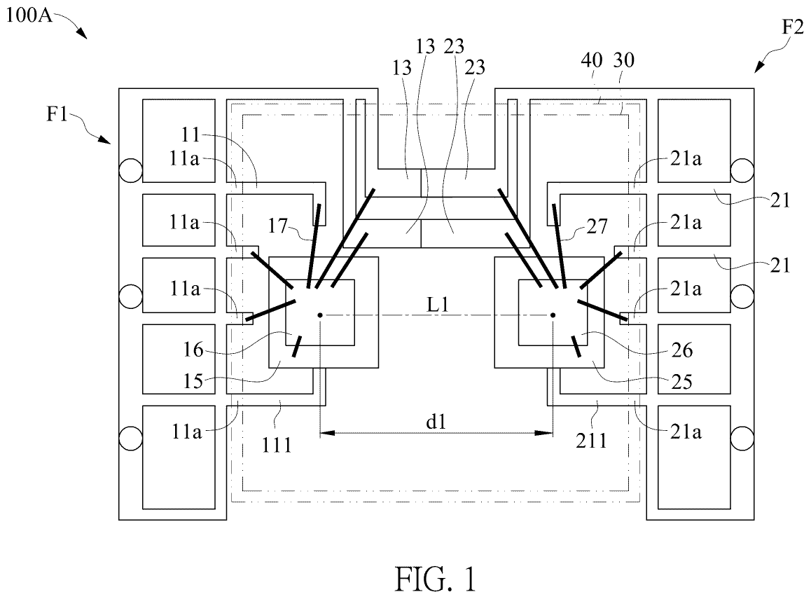

Referring to FIG. 1, FIG. 1 is a schematic view of a capacitive coupling package structure 100A according to one embodiment of the present disclosure. The capacitive coupling package structure 100A includes a plurality of first leads 11, a plurality of second leads 21, two first coupling plates 13, two second coupling plates 23, a first chip 16, a second chip 26, a first package member 30, and a second package member 40. The first chip 16 is electrically connected to the plurality of first leads 11 and the two first coupling plates 13. The second chip 26 is electrically connected to the plurality of second leads 21 and the two second coupling plates 23. The first package member 30 encapsulates the plurality of first leads 11, the plurality of second leads 21, the first chip 26, the second chip 26, the two first coupling plates 13, and the two second coupling plates 23. The second package member 40 encapsulates the first package member 30, the plurality of first leads 11, and the plurality of second leads 21. End portions of the two first coupling plates 13 and the two second coupling plates 23 are not exposed from the second package member 40. End portions of the plurality of first leads 11 and the plurality of second leads 21 are exposed from the second package member 40. The two first coupling plates 13 and the two second coupling plates 23 are vertically separate from each other and that are partially and vertically overlapped with each other (details thereof will be described below), respectively. As shown in FIG. 1, the first chip 16 can be electrically connected to the plurality of first leads 11 and the two first coupling plates 13 via soldering wires 17, the second chip 26 can be electrically connected to the plurality of second leads 21 and the two second coupling plates 23 via soldering wires 27, and the first chip 16 is spaced apart from the second chip 26 by a horizontal distance d1.

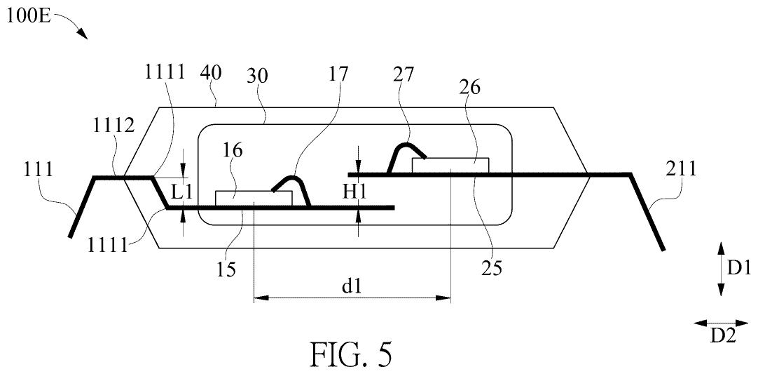

In this embodiment, the capacitive coupling package structure 100A further includes a first placement pad 15 and a second placement pad 25, the first chip 16 is fixed to the first placement pad 15, and the second chip 26 is fixed to the second placement pad 25. In addition, the plurality of first leads 11 include a first placement pad lead 111, and the first placement pad 15 is connected to the first placement pad lead 111. The plurality of second leads 21 include a second placement pad lead 211, and the second placement pad 25 is connected to the second placement pad lead 211. In certain embodiments, the first placement pad 15 and the second placement pad 25 are disposed at a same height along a vertical direction D1 (as shown in FIG. 5). In other embodiments, the first placement pad 15 and the second placement pad 25 have a height difference therebetween. The aforementioned height difference is greater than 200 μm; however, according to certain embodiments, the aforementioned height difference is greater than or equal to 400 μm.

According to the embodiment as shown in FIG. 1, a center of the first chip 16 and a center of the second chip 26 define an axis L1 therebetween as viewed in an orthogonal projection direction (the vertical direction D1), and the two first coupling plates 13 and the two second coupling plates 23 are located on one side of the axis L1. Each of the two first coupling plates 13 and a corresponding one of the two second coupling plates 23 form a signal channel. In the embodiment as shown in FIG. 1, the two signal channels are located on one side of the axis L1.

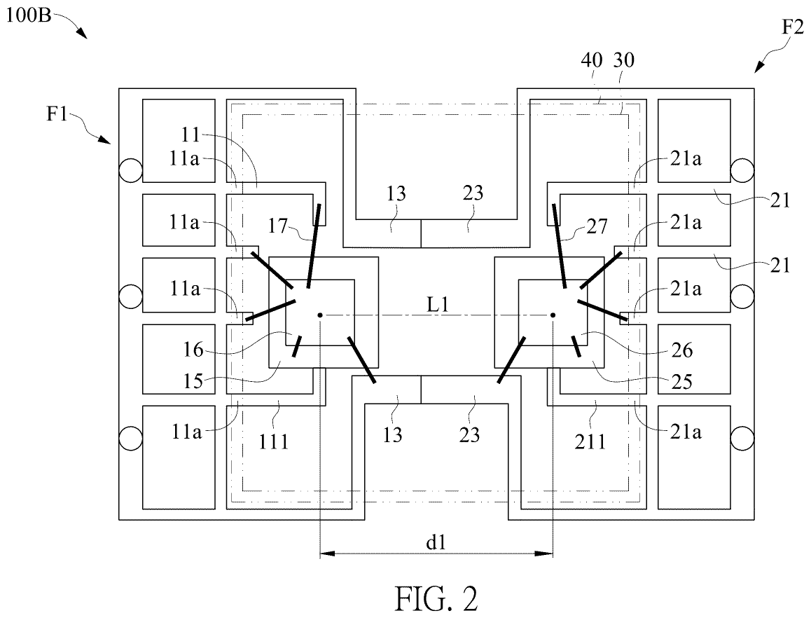

Referring to FIG. 2, FIG. 2 is a schematic view of a capacitive coupling package structure 100B according to one embodiment of the present disclosure. In this embodiment, the two first coupling plates 13 and the two second coupling plates 23 are located on two sides of the axis L1, respectively. That is, the two signal channels are located on the two sides of the axis L1, respectively.

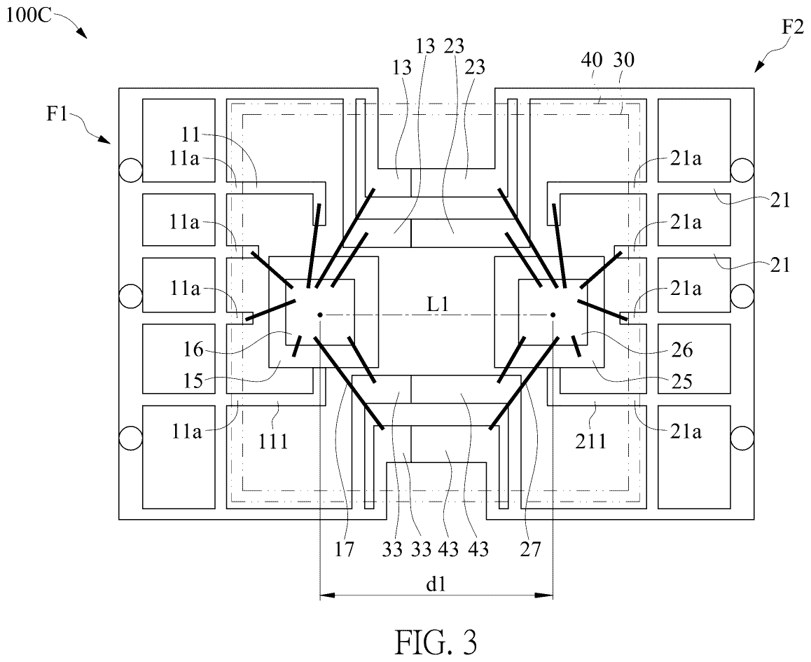

Referring to FIG. 3, FIG. 3 is a schematic view of a capacitive coupling package structure 100C according to one embodiment of the present disclosure. In this embodiment, the capacitive coupling package structure 100C further includes two third coupling plates 33 and two fourth coupling plates 43. The two third coupling plates 33 and the two fourth coupling plates 43 are vertically separate from each other, and are partially and vertically overlapped with each other (details thereof will be described below). The two third coupling plates 33 and the two fourth coupling plates 43 are located on another side of the axis L1. By such a structural design, the capacitive coupling package structure 100C can include four signal channels.

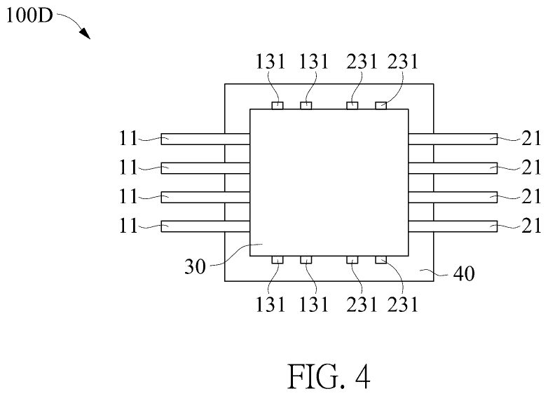

Referring to FIG. 4, FIG. 4 is a schematic view of a capacitive coupling package structure 100D according to one embodiment of the present disclosure. In this embodiment, end portions 131 of the two first coupling plates 13 and end portions 231 of the two second coupling plates 23 are exposed from the first package member 30, and are encapsulated by the second package member 40. In the aforementioned descriptions, the end portions 131 and 231 are not exposed from the second package member 40, indicating that the end portions 131 and 231 are located in the second package member 40 (as shown in FIG. 4). However, the present disclosure is not limited thereto. In certain embodiments, the end portions 131 of the two first coupling plates 13 and the end portions 231 of the two second coupling plates 23 are flush with the second package member 40 (not shown in the figures). In the embodiment as shown in FIG. 4, end portions 331 of the two third coupling plates 33 and end portions 431 of the two fourth coupling plates 43 are exposed from the first package member 30, and are encapsulated by the second package member 40.

Referring to FIG. 5, FIG. 5 is a schematic side view of a capacitive coupling package structure 100E according to one embodiment of the present disclosure. In this embodiment, the two first coupling plates 13 and the two second coupling plates 23 have a first vertical distance H1 therebetween, and the first vertical distance H1 is greater than 200 μm. In certain embodiments, the first vertical distance H1 is greater than or equal to 400 μm. A vertical distance refers to a distance in the vertical direction D1. In a dual package space formed by the first package member 30 and the second package member 40, a space is limited, such that requirements of creepage and clearance can be met for the capacitive coupling package structure 100E within the aforementioned vertical distance range. Similarly, as shown in FIG. 3, in certain embodiments, the two third coupling plates 33 and the two fourth coupling plates 43 have a second vertical distance therebetween (not shown in the figures), and the second vertical distance is greater than 200 μm. In certain embodiments, the second vertical distance is greater than or equal to 400 μm. Accordingly, in a dual package space formed by the first package member 30 and the second package member 40, a space in limited, such that isolation requirements can be met for the capacitive coupling package structure 100E within the aforementioned vertical distance range.

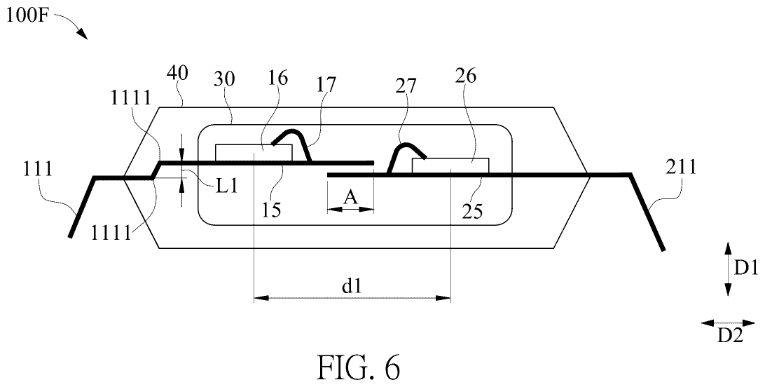

Referring to FIG. 6, FIG. 6 is a schematic side view of a capacitive coupling package structure 100F according to one embodiment of the present disclosure. In this embodiment, the two first coupling plates 13 and the two second coupling plates 23 have a first vertical overlapping area A therebetween, such that a capacitance formed between each of the two first coupling plates 13 and a corresponding one of the two second coupling plates 23 according to the first vertical overlapping area A is greater than 10 fF (f is referred to as femtofarad, which is a unit below pF, and 1 pF=1000 f). The first vertical overlapping area A is an overlapping area of the two first coupling plates 13 and the two second coupling plates 23 projected along the vertical direction D1 on a plane parallel to a horizontal direction D2. Within a range of the first vertical overlapping area A, an effect of miniaturization of the capacitive coupling package structure 100F can be achieved, and requirements of creepage and clearance can be met for the capacitive coupling package structure 100F. Similarly, referring to FIG. 3, in certain embodiments, the two third coupling plates 33 and the two fourth coupling plates 43 have a second vertical overlapping area (not shown in the figures) therebetween, such that a capacitance formed between each of the two third coupling plates 33 and a corresponding one of the two fourth coupling plates 43 according to the second vertical overlapping area is greater than 10 ff. In certain embodiments, the second vertical overlapping area is equal to the first vertical overlapping area A.

Reference is further made to FIG. 4 and FIG. 5. In certain embodiments, the two third coupling plates 33 and the two fourth coupling plates 43 have a second vertical distance therebetween (not shown in the figures), and the second vertical distance is greater than 200 μm. In certain embodiments, the second vertical distance is greater than or equal to 400 μm. Accordingly, in a dual package space formed by the first package member 30 and the second package member 40, a space in limited, such that isolation requirements can be met for the capacitive coupling package structure within the aforementioned vertical distance range.

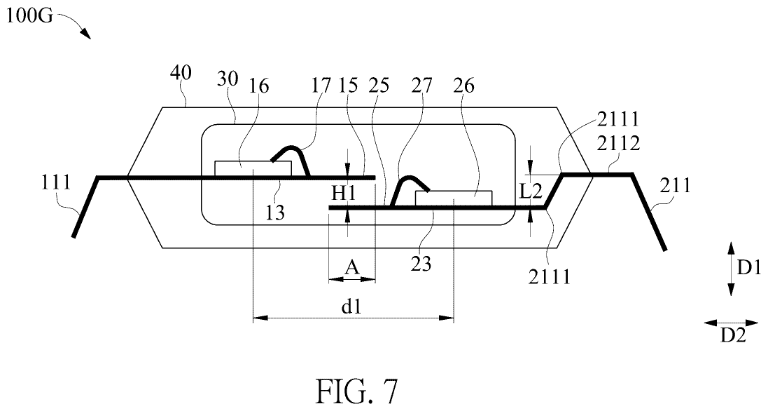

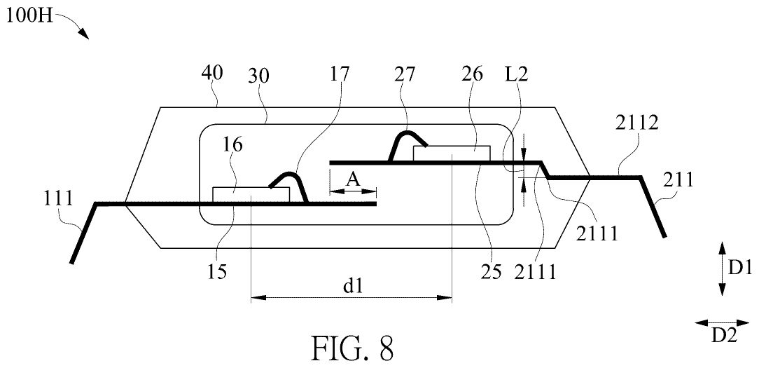

Referring to FIG. 7 and FIG. 8, FIG. 7 and FIG. 8 are side views of capacitive coupling package structures 100G and 100H according to embodiments of the present disclosure. One of the differences between FIG. 7 and FIG. 8 is that, relative positions of the two first coupling plates 13 and the two second coupling plates 23 are different in the vertical direction D1. The two first coupling plates 13 and the two second coupling plates 23 have the first vertical distance H1 therebetween, and the first vertical distance H1 equals to the height difference between the first placement pad 15 and the second placement pad 25.

According to certain embodiments, at least one of the first placement pad lead 11I and the second placement pad lead 211 has two bent portions. In the embodiments as shown in FIG. 7 and FIG. 8, the second placement pad lead 211 has two bent portions 2111, such that the first placement pad 15 and the second placement pad 25 have the aforementioned height difference therebetween. The two bent portions 2111 are located outside the first package member 30, and are encapsulated by the second package member 40. Furthermore, the second placement pad lead 211 has a body portion 2112 in addition to the two bent portions 2111, and a turning angle is defined between one of the two bent portions 2111 and the body portion 2112. Naturally, the present disclosure is not limited to only the second placement pad lead 211 having the two bent portions 2111. According to certain embodiments, the first placement pad lead 111 and the second placement pad lead 211 both have bent portions. In other embodiments, at least one of the first placement pad lead 111 and the second placement pad lead 211 has bent portions, and another one of the first placement pad lead 111 and the second placement pad lead 211 does not have bent portions. However, the present disclosure is not limited thereto.

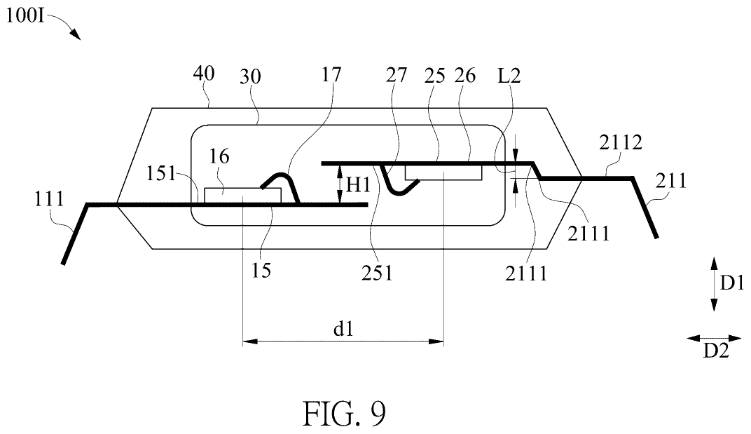

Referring to FIG. 9, FIG. 9 is a schematic side view of a capacitive coupling package structure 1001 according to one embodiment of the present disclosure. In this embodiment, the first placement pad 15 has a first placement surface 151, the second placement pad 25 has a second placement surface 251, and the first placement surface 151 and the second placement surface 151 face each other. In other words, the first chip 16 is opposite to the second chip 26 on the vertical direction D1. Therefore, an effect of miniaturization of the capacitive coupling package structure 1001 can be achieved, and requirements of creepage and clearance can be met for the capacitive coupling package structure 1001.

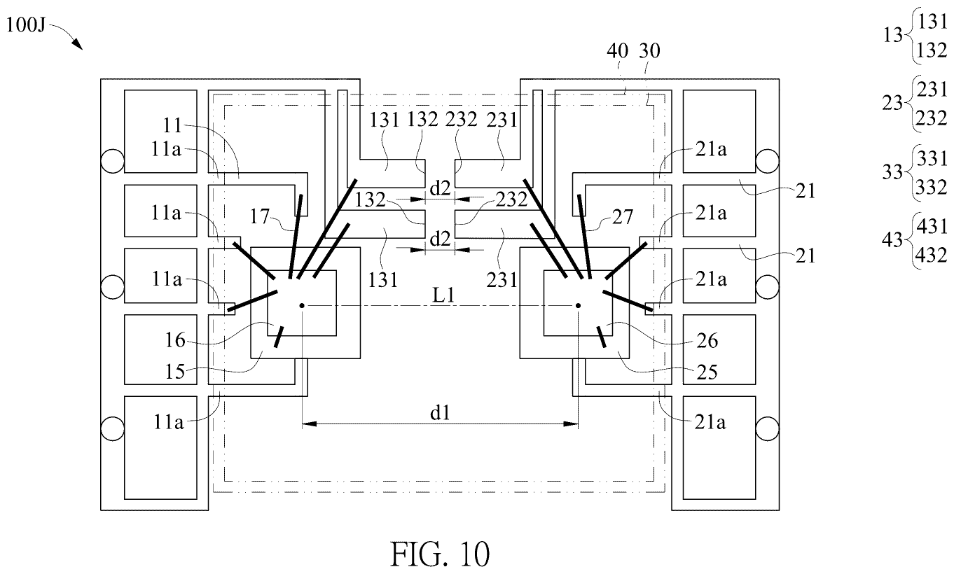

Referring to FIG. 10, FIG. 10 is a schematic view of a capacitive coupling package structure 100J according to one embodiment of the present disclosure. One of the differences between this embodiment and the embodiments as shown in FIG. 3 is that, the two first coupling plates 13 are perpendicular to a plane defined by the plurality of first leads 11, and the two second coupling plates 23 are perpendicular to a plane defined by the plurality of second leads 21. The two first coupling plates 13 and the two second coupling plates 23 are horizontally separate from each other and are partially and horizontally overlapped with each other, respectively (details thereof will be described below).

According to the embodiment as shown in FIG. 10, a center of the first chip 16 and a center of the second chip 26 define an axis L1 therebetween as viewed in an orthogonal projection direction (the vertical direction D1), and the two first coupling plates 13 and the two second coupling plates 23 are located on one side of the axis L1. Each of the two first coupling plates 13 and a corresponding second coupling plate 23 form a signal channel.

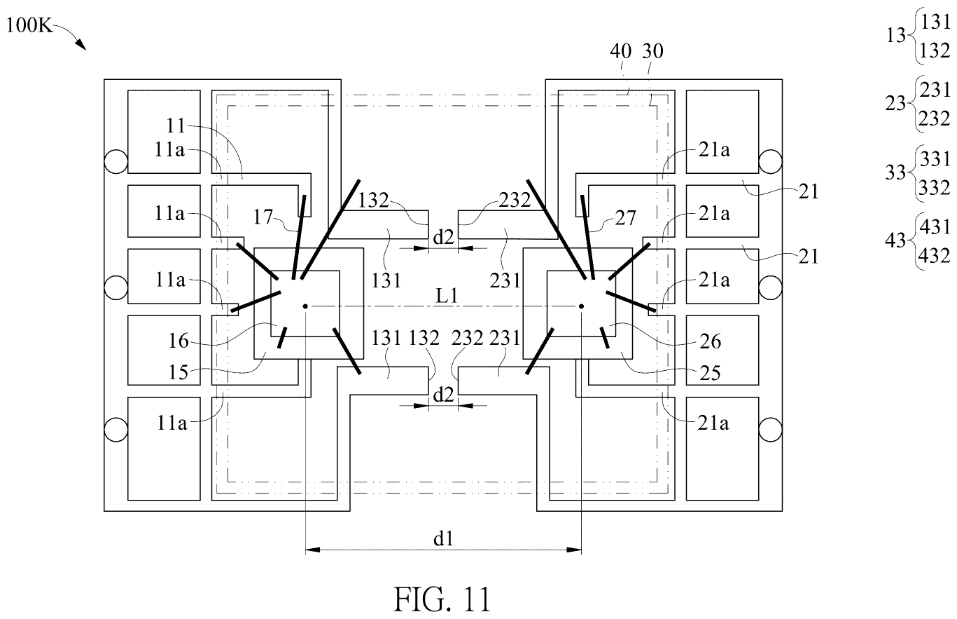

Referring to FIG. 11, FIG. 11 is a schematic view of a capacitive coupling package structure 100K according to one embodiment of the present disclosure. In this embodiment, the two first coupling plates 13 and the two second coupling plates 23 are located on two sides of the axis L1, respectively. That is, the two signal channels are located on the two sides of the axis L1, respectively. In this embodiment, the two signal channels are not limited to being located on the same side or on different sides of the axis L1.

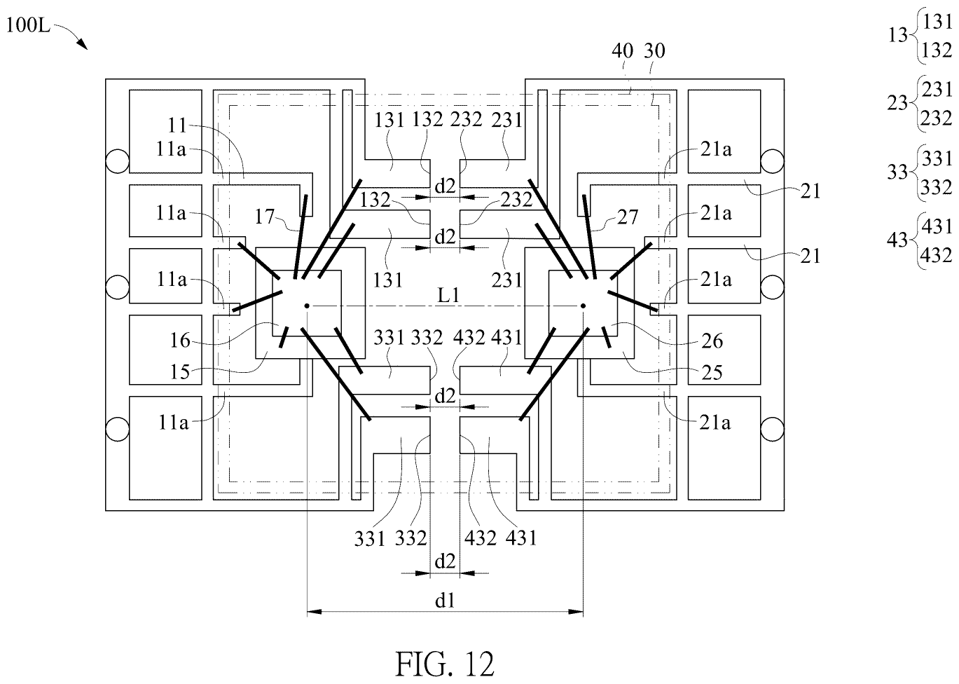

Referring to FIG. 12, FIG. 12 is a schematic view of a capacitive coupling package structure 100L according to one embodiment of the present disclosure. In this embodiment, the capacitive coupling package structure 100L further includes the two third coupling plates 33 and the two fourth coupling plates 43, and the two third coupling plates 33 and the two fourth coupling plates 43 are horizontally separate from each other and are partially and horizontally overlapped with each other, respectively (details thereof will be described below). The two third coupling plates 33 and the two fourth coupling plates 43 are located on another side of the axis L1. The two third coupling plates 33 are perpendicular to the plane defined by the plurality of first leads 11, and the two fourth coupling plates 43 are perpendicular to a plane defined by the plurality of second leads 21. By such a structural design, the capacitive coupling package structure 100L has four signal channels.

In this embodiment, the capacitive coupling package structure 100L further includes the first placement pad 15 and the second placement pad 25. The first chip 16 is fixed to first placement pad 15 and the second chip 26 is fixed to the second placement pad 25. In addition, the plurality of first leads 11 include a first placement pad lead 111, and the first placement pad 15 is connected to the first placement pad lead 111. The plurality of second leads 21 include a second placement pad lead 211, and the second placement pad 25 is connected to the second placement pad lead 211.

Similarly, referring to FIG. 2, the end portions of the two first coupling plates 13 and the two second coupling plates 23 (i.e., the end portions 131 of the two first coupling plates 13 and the end portions 231 of the two second coupling plates 23) of the capacitive coupling package structure 100L are exposed from the first package member 30, and are encapsulated by the second package member 40. Furthermore, the end portions 331 of the two third coupling plates 33 and the end portions 431 of the two fourth coupling plates 43 are exposed from the first package member 30, and are encapsulated by the second package member 40.

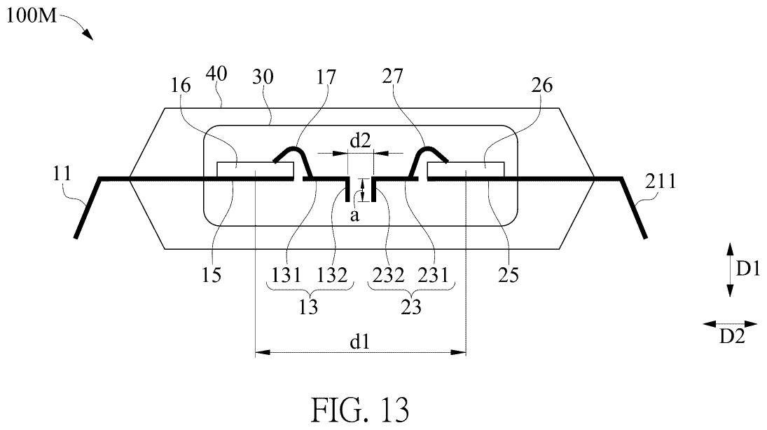

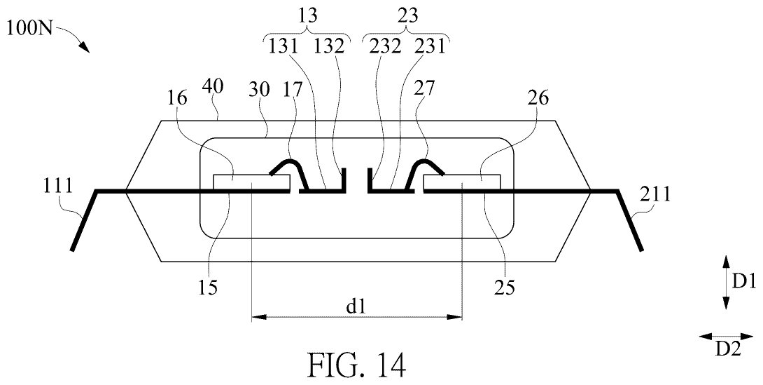

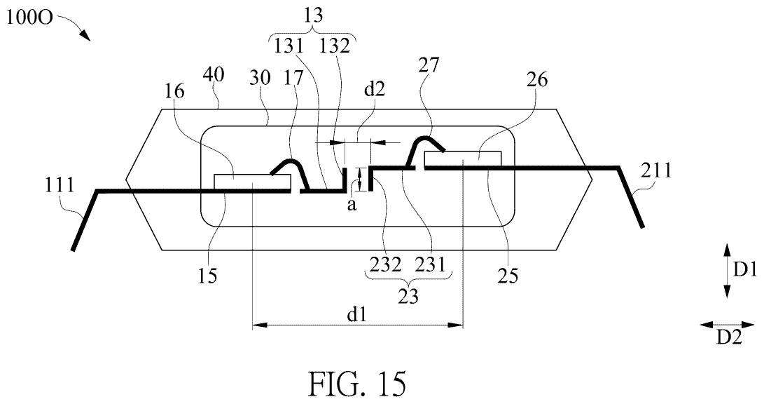

Referring to FIG. 13 to FIG. 15, FIG. 13 is a schematic side view of a capacitive coupling package structure 100M according to one embodiment of the present disclosure, FIG. 14 is a schematic side view of a capacitive coupling package structure 100N according to one embodiment of the present disclosure, and FIG. 15 is a schematic side view of a capacitive coupling package structure 100O according to one embodiment of the present disclosure. In these embodiments, the two first coupling plates 13 and the two second coupling plates 23 each have end portions (i.e., the end portions 131 of the two first coupling plates 13 and the end portions 231 of the two second coupling plates 23) and respectively have extension portions 132 and 232 that are bent. Each extension portion (i.e., each of the extension portions 132 and the extension portions 232) is substantially perpendicular to a corresponding end portion (i.e., a corresponding one of the end portions 131 and the end portions 231). The extension portions 132 of the two first coupling plates 13 and the extension portions 232 of the two second coupling plates 23 have a second horizontal distance d2 therebetween, and the second horizontal distance d2 is greater than 200 μm. According to certain embodiments, the second horizontal distance d2 is greater than or equal to 400 μm. Furthermore, in this embodiment, the two first coupling plates 13 and the two second coupling plates 23 have a first horizontal overlapping area a therebetween, the first horizontal overlapping area a is an area in which the extension portions 132 and the extension portions 232 overlapping with each other along the horizontal direction D2, and the first horizontal overlapping area a allows a capacitance formed between each the two first coupling plates 13 and a corresponding one of the two second coupling plates 23 to be greater than 10 ff. In the embodiments as shown in FIG. 13 and FIG. 14, the extension portions 132 of the two first coupling plates 13 and the extension portions 232 of the two second coupling plates 23 are extended in the same direction. However, the present disclosure is not limited thereto, and according to the embodiment as shown in FIG. 15, the extension portions 132 of the two first coupling plates 13 and the extension portions 232 of the two second coupling plates 23 are extended in different directions. Furthermore, according to the embodiments as shown in FIG. 13 and FIG. 14, the first placement pad 15 and the second placement pad 25 have the same height in the vertical direction D1, and according to the embodiment as shown in FIG. 15, the first placement pad 15 and the second placement pad 25 have a height difference therebetween.

Reference is further made to 13 to FIG. 15. In certain embodiments, the two third coupling plates 33 and the two fourth coupling plates 43 of the capacitive coupling package structure each have the end portions and the extension portion that are bent (not shown in figures). Extension portions of the two third coupling plates 33 and the two fourth coupling plates 43 have a second horizontal distance therebetween, and the second horizontal distance is greater than 200 μm. According to certain embodiments, the second horizontal distance is greater than or equal to 400 μm. Furthermore, the two first coupling plates 13 and the two second coupling plates 23 have a second horizontal overlapping area therebetween, the second horizontal overlapping area is an area in which the two extension portions overlap with each other along the horizontal direction D2, and the second horizontal overlapping area allows a capacitance formed between each of the two third coupling plates 33 and a corresponding one of the two fourth coupling plates 43 to be greater than 10 fF. Similarly, the extension portion of the two third coupling plates 33 and the extension portion of the two fourth coupling plates 43 can be extended in the same direction or different directions.

Referring to FIG. 15, according to certain embodiments, at least one of the first placement pad lead 111 and the second placement pad lead 211 has two bent portions (not shown in figures), such that the first placement pad 15 and the second placement pad 25 have a height difference therebetween.

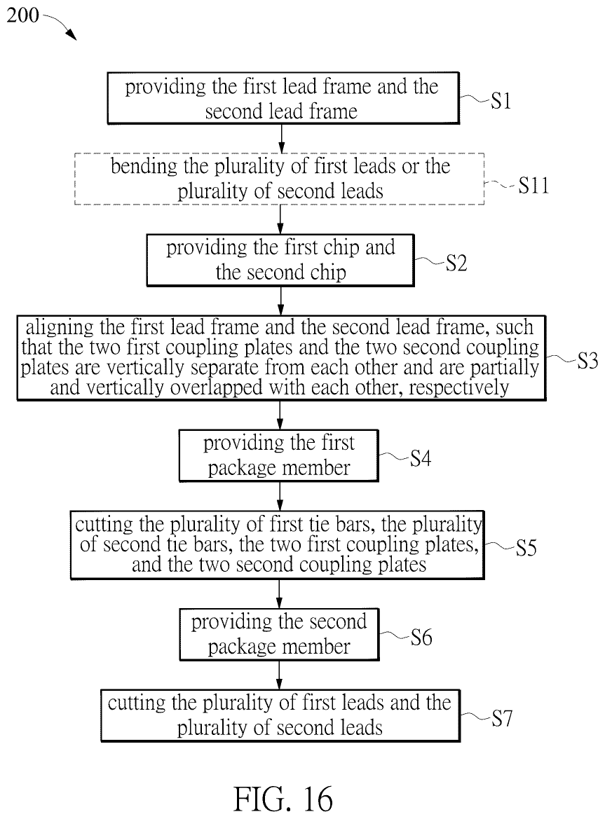

Referring to FIG. 16, which is to be read in conjunction with FIG. 3 and FIG. 4, FIG. 16 is a flowchart of a manufacturing method 200 for a capacitive coupling package structure according to one embodiment of the present disclosure. The manufacturing method 200 includes the following steps.

Step S1 includes: providing the first lead frame F1 and the second lead frame F2, the first lead frame F1 including the plurality of first leads 11 and the two first coupling plates 13, and the second lead frame F2 including the plurality of second leads 21 and the two second coupling plates 23; the plurality of first tie bars 11a being disposed between the plurality of first leads 11 and the plurality of second tie bars 21a being disposed between the plurality of second leads 21. The first lead frame F1 and the second lead frame F2 can be flat structures.

Step S2 includes: providing the first chip 16 and the second chip 26, the first chip 16 being electrically connected to the plurality of first leads 11 and the two first coupling plates 13, and the second chip 26 being electrically connected to the plurality of second leads 21 and the two second coupling plates 23.

Step S3 includes: aligning the first lead frame F1 and the second lead frame F2, such that the two first coupling plates 13 and the two second coupling plates 23 are vertically separate from each other and are partially and vertically overlapped with each other, respectively. Details regarding “the two first coupling plates 13 and the two second coupling plates 23 being vertically separate from each other and are partially and vertically overlapped with each other, respectively,” can be referred to in abovementioned descriptions of the capacitive coupling package structures.

Step S4 includes: providing the first package member 30 to encapsulate the plurality of first leads 11, the plurality of second leads 13, the two first coupling plates 13, the two second coupling plates 23, the first chip 16, and the second chip 26. In certain embodiments, a main material of the first package member 30 is epoxy resin. Furthermore, the first package member 30 is made of materials such as epoxy resin, phenolic resin, catalyst, and silica micropowder.

Step S5 includes: cutting the plurality of first tie bars 11a, the plurality of second tie bars 21a, the two first coupling plates 13 (e.g., the end portions), and the two second coupling plates 23 (e.g., the end portions).

Step S6 includes: providing the second package member 40 to encapsulate the first package member 30, the plurality of first leads 11, and the plurality of second leads 21, such that the end portions of the two first coupling plates 13 and the two second coupling plates 23 are not exposed from the second package member 40.

Step S7 includes: cutting the plurality of first leads 11 and the plurality of second leads 21. A capacitive coupling package structure is manufactured as shown in FIG. 4.

According to certain embodiments, as shown in FIG. 3, the first lead frame F1 further includes the two third coupling plates 33, and the second lead frame F2 further includes the two fourth coupling plates 43. The step S3 further includes aligning the two third coupling plates 33 and the two fourth coupling plates 43, such that the two third coupling plates 33 and the two fourth coupling plates 43 are vertically separate from each other and are partially and vertically overlapped with each other, respectively.

According to certain embodiments, before the step S2, a step S11 is performed. Step S11 includes: bending the plurality of first leads 11 or the plurality of second leads 21, such that the plurality of first leads 11 or the plurality of second leads 21 have the bent portions (as shown in FIG. 5 or FIG. 7), and a height difference is present between the first placement pad 15 and the second placement pad 25.

According to certain embodiments, before disposing the second package member 40, an inversion step is further performed (not shown in the figures). The inversion step includes: inverting the first lead frame F1 or inverting the second lead frame F2 (e.g., inverting by 180 degrees along the axis L1), such that a top surface of the first chip 16 is opposite to a top surface of the second chip 26, as shown in FIG. 9.

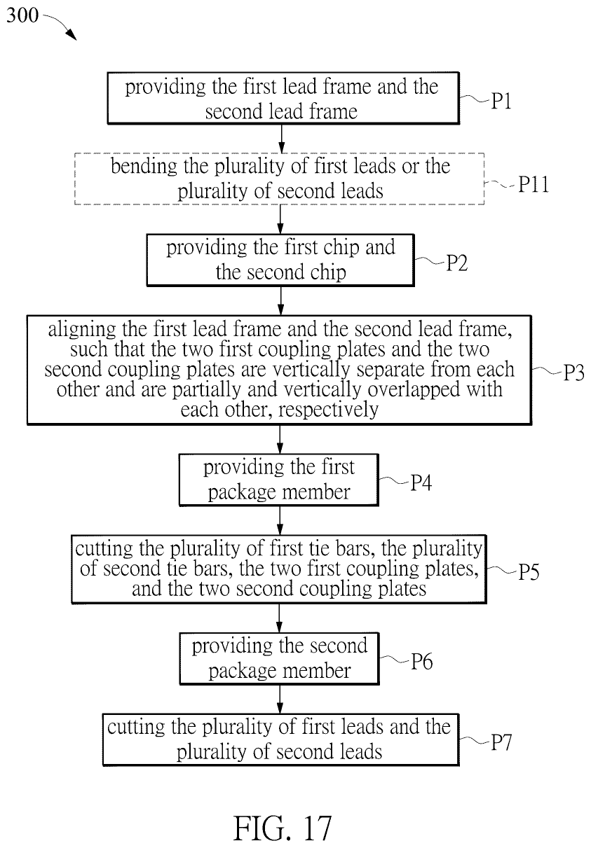

Referring to FIG. 17, which is to be read in conjunction with FIG. 11 to FIG. 14, FIG. 17 is a flowchart of a manufacturing method 300 for a capacitive coupling package structure according to one embodiment of the present disclosure. The manufacturing method 300 includes the following steps.

Step P1 includes: providing the first lead frame F1 and the second lead frame F2, the first lead frame F1 including the plurality of first leads 11 and the two first coupling plates 13, and the second lead frame F2 including the plurality of second leads 21 and the two second coupling plates 23; and the plurality of first tie bars 11a being disposed between the plurality of first leads 11, and the plurality of second tie bars 21a being disposed between the plurality of second leads 21.

Step P2 includes: providing the first chip 16 and the second chip 26, the first chip 16 being electrically connected to the plurality of first leads 11 and the two first coupling plates 13, and the second chip 26 being electrically connected to the plurality of second leads 21 and the two second coupling plates 23.

Step P3 includes: aligning the first lead frame F1 and the second lead frame F2, such that the two first coupling plates 13 and the two second coupling plates 23 are horizontally separate from each other and are partially and horizontally overlapped with each other, respectively.

Step P4 includes: providing the first package member 30 to encapsulate the plurality of first leads 11, the plurality of second leads 13, the two first coupling plates 13, the two second coupling plates 23, the first chip 16, and the second chip 26.

Step P5 includes: cutting the plurality of first tie bars 11a, the plurality of second tie bars 21a, the two first coupling plates 13, and the two second coupling plates 23.

Step P6 includes: providing the second package member 40 to encapsulate the first package member 30, the plurality of first leads 11, and the plurality of second leads 21, such that the end portions of the two first coupling plates 13 and the two second coupling plates 23 are not exposed from the second package member 40.

Step P7 includes: cutting the plurality of first leads 11 and the plurality of second leads 21.

A difference between the embodiments as shown in FIG. 16 and FIG. 17 is that, in the embodiment as shown in FIG. 16, the two first coupling plates 13 and the two second coupling plates 23 are vertically separate from each other and are partially and vertically overlapped with each other, respectively; in the embodiment as shown in FIG. 17, the two first coupling plates 13 and the two second coupling plates 23 are horizontally separate from each other and are partially and horizontally overlapped with each other, respectively.

According to certain embodiments, before the step P2 (providing the first chip 16 and the second chip 26), the two first coupling plates 13 and the two second coupling plates 23 can be bent, such that the two first coupling plates 13 and the two second coupling plates 23 are horizontally separate from each other and are partially and horizontally overlapped with each other, respectively (as shown in FIG. 13). For example, each of the extension portions 132 of the two first coupling plates 13 is opposite to and parallel with each of the extension portions 232 of the two second coupling plates 23. According to certain embodiments, the two first coupling plates 13 and the two second coupling plates 23 are bent in the same direction, as shown in FIG. 13 and FIG. 14. However, the present disclosure is not limited thereto, and according to other embodiments, the two first coupling plates 13 and the two second coupling plates 23 are bent in different directions, as shown in FIG. 15.

According to certain embodiments, before the step P2, a step P11 is performed. Step P11 includes: bending the plurality of first leads 11 or the plurality of second leads 21, such that the plurality of first leads 11 or the plurality of second leads 21 have the bent portions, and a height difference is present between the first placement pad 15 and the second placement pad 25.

According to certain embodiments, as shown in FIG. 12, the first lead frame F1 further includes the two third coupling plates 33, and the second lead frame F2 further includes the two fourth coupling plates 43. The step P3 further includes aligning the two third coupling plates 33 and the two fourth coupling plates 43, such that the two third coupling plates 33 and the two fourth coupling plates 43 are horizontally separate from each other and are partially and horizontally overlapped with each other, respectively.

According to certain embodiments, before the step S2 (providing the first chip 16 and the second chip 26), the two third coupling plates 33 and the two fourth coupling plates 43 are bent, such that each of the extension portions of the two third coupling plates 33 is opposite to and parallel with each of the extension portions of the two fourth coupling plates 43. Similarly, the two third coupling plates 33 and the two fourth coupling plates 43 can be bent in the same direction or different directions.

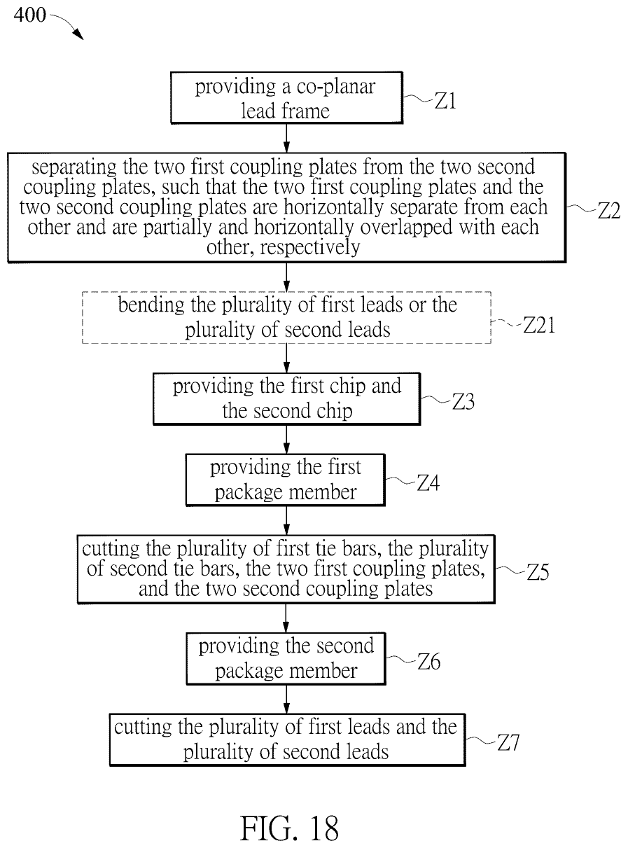

Referring to FIG. 18, which is to be read in conjunction with FIG. 12 to FIG. 15, FIG. 18 is a flowchart of a manufacturing method 400 for a capacitive coupling package structure according to one embodiment of the present disclosure. The manufacturing method 400 includes the following steps.

Step Z1 includes: providing a co-planar lead frame, the co-planar lead frame including the plurality of first leads 11, the plurality of second leads 21, the two first coupling plates 13, and the two second coupling plates 23; the two first coupling plates 13 being connected to the two second coupling plates 23, respectively; and the plurality of first tie bars 11a being disposed between the plurality of first leads 11, and the plurality of second tie bars 21a being disposed between the plurality of second leads 21.

Step Z2 includes: separating the two first coupling plates 13 from the two second coupling plates 23, such that the two first coupling plates 13 and the two second coupling plates 23 are horizontally separate from each other and are partially and horizontally overlapped with each other, respectively.

Step Z3 includes: providing the first chip 16 and the second chip 26, the first chip 16 being electrically connected to the plurality of first leads 11 and the two first coupling plates 13, and the second chip 26 being electrically connected to the plurality of second leads 21 and the two second coupling plates 23.

Step Z4 includes: providing the first package member 30 to encapsulate the plurality of first leads 11, the plurality of second leads 21, the two first coupling plates 13, the two second coupling plates 23, the first chip 16, and the second chip 26.

Step Z5 includes: cutting the plurality of first tie bars 11a, the plurality of second tie bars 21a, the two first coupling plates 13, and the two second coupling plates 23.

Step Z6 includes: providing a second package member 40 to encapsulate the first package member 30, the plurality of first leads 11, and the plurality of second leads 21, such that the end portions of the two first coupling plates 13 and the two second coupling plates 23 are not exposed from the second package member 40.

Step Z7 includes: cutting the plurality of first leads 11 and the plurality of second leads 21.

A difference between the embodiments as shown in FIG. 18 and FIG. 17 is that, the co-planar lead frame includes the first lead frame F1 and the second lead frame F2. For example, the co-planar lead frame is an integral structure, such that the two first coupling plates 13 are connected to the two second coupling plates 23. In certain embodiments, the two first coupling plates 13 can be separated from the two second coupling plates 23 by using a stamping press. Furthermore, the separation process can further include bending the two first coupling plates 13 and the two second coupling plates 23. For example, a stamping press is used to pass through a cutting opening between the two first coupling plates 13 and the two second coupling plates 23. At this time, because a width of the stamping press is greater than the cutting opening, the two first coupling plates 13 and the two second coupling plates 23 can be bent. At this time, the two first coupling plates 13 and the two second coupling plates 23 are bent in the same direction. However, in certain embodiments, the two first coupling plates 13 and the two second coupling plates 23 are bent in different directions.

According to certain embodiments, as shown in FIG. 12, the co-planar lead frame further includes the two third coupling plates 33 and the two fourth coupling plates 43. The step Z3 further includes aligning the two third coupling plates 33 and the two fourth coupling plates 43, such that the two third coupling plates 33 and the two fourth coupling plates 43 are horizontally separate from each other and are partially and horizontally overlapped with each other, respectively. In addition, the two third coupling plates 33 and the two fourth coupling plates 43 can be bent, and the two third coupling plates 33 and the two fourth coupling plates 43 can be bent in the same direction or different directions.

According to certain embodiments, before the step Z2, a step Z21 is performed. Step Z21 includes: bending the plurality of first leads 11 or the plurality of second leads 21, such that the plurality of first leads 11 or the plurality of second leads 21 have the bent portions, and a height difference is present between the first placement pad 15 and the second placement pad 25.

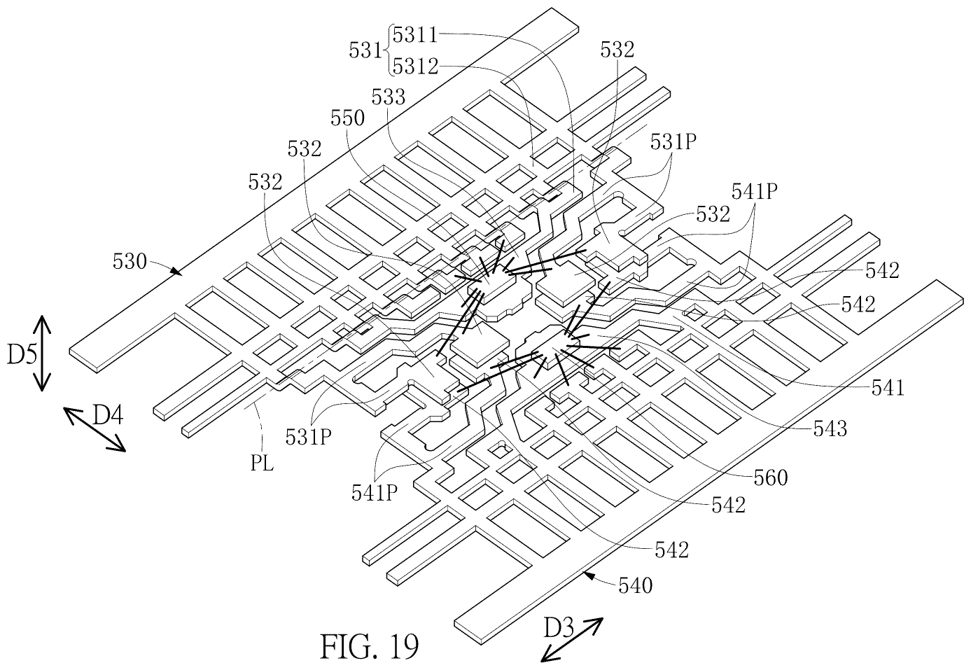

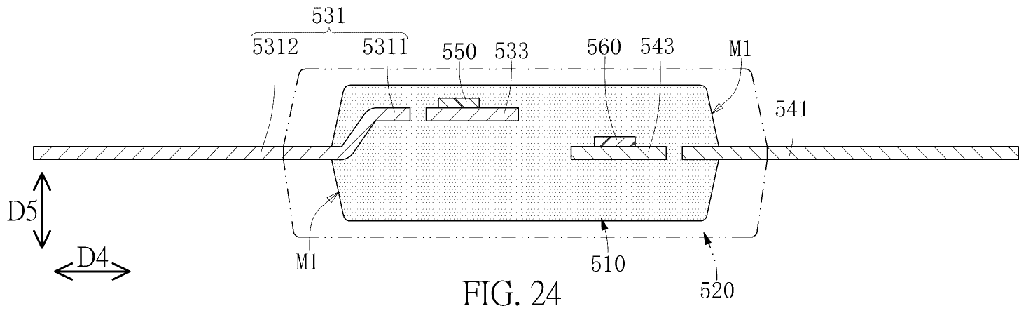

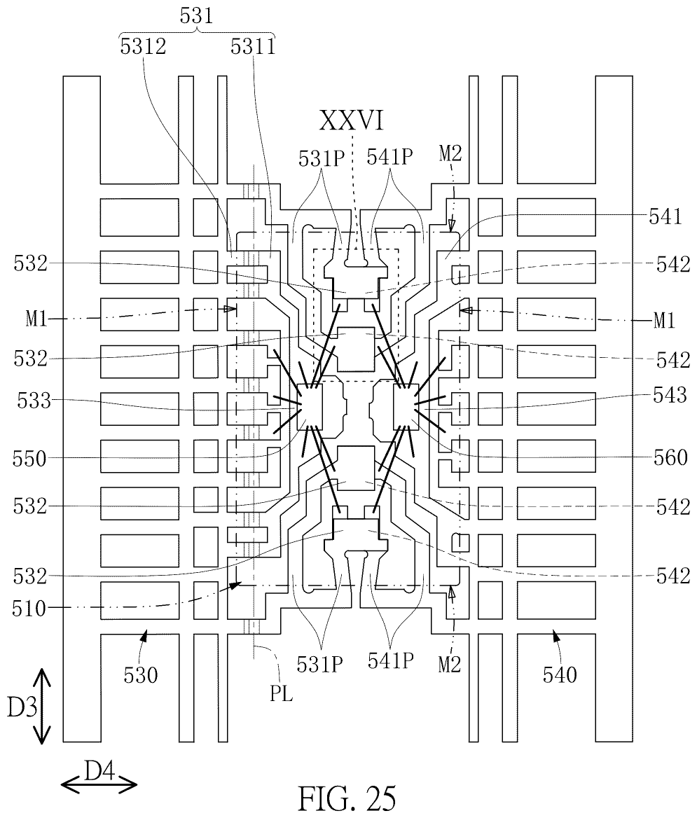

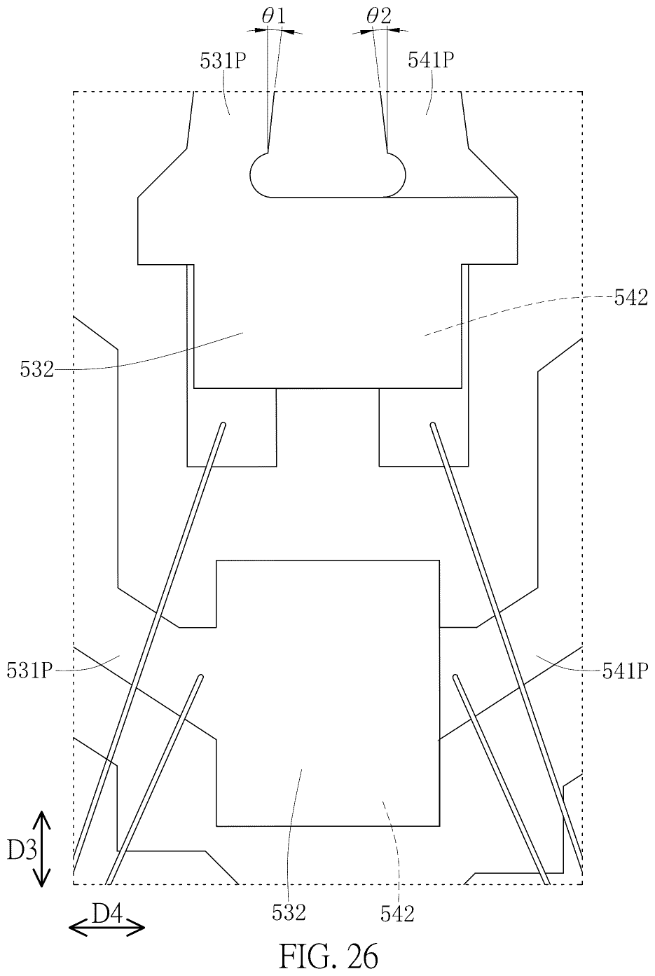

Referring to FIG. 19 to FIG. 26, FIG. 19 to FIG. 26 show the capacitive coupling package structure 500 in another implementation. Specifically, as shown in FIG. 24, the capacitive coupling package structure 500 may include a first package member 510, a second package member 520 covering the first package member 510, a first conductive component 530 and a second conductive component 540 disposed in the first package member 510, and a first chip 550 and a second chip 560 that are respectively and electrically coupled to the first conductive component 530 and the second conductive component 540. The following description describes the structure and connection relation of each component of the capacitive coupling package structure 500.

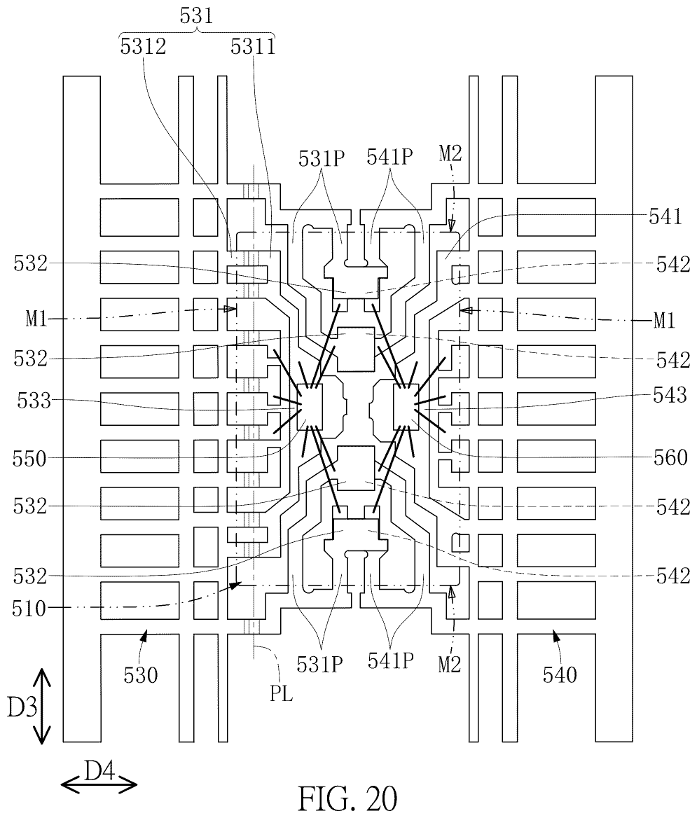

Referring to FIG. 20 to FIG. 22, the first package member 510 has two first sides M1 and two second sides M2 that are opposite to the two first sides M1 and are connected to the two first sides M2. In the present embodiment, the first package member 510 has a length direction D3 (e.g., a Y-axis direction on a plane of FIG. 20) and a width direction D4 perpendicular to the length direction (e.g., a X-axis direction on a plane of FIG. 20). The cross-sections of the first package member 510 along both the length direction D3 and the width direction D4 are hexagonal. Additionally, when viewed from the top view, the first package member 510 appears rectangular.

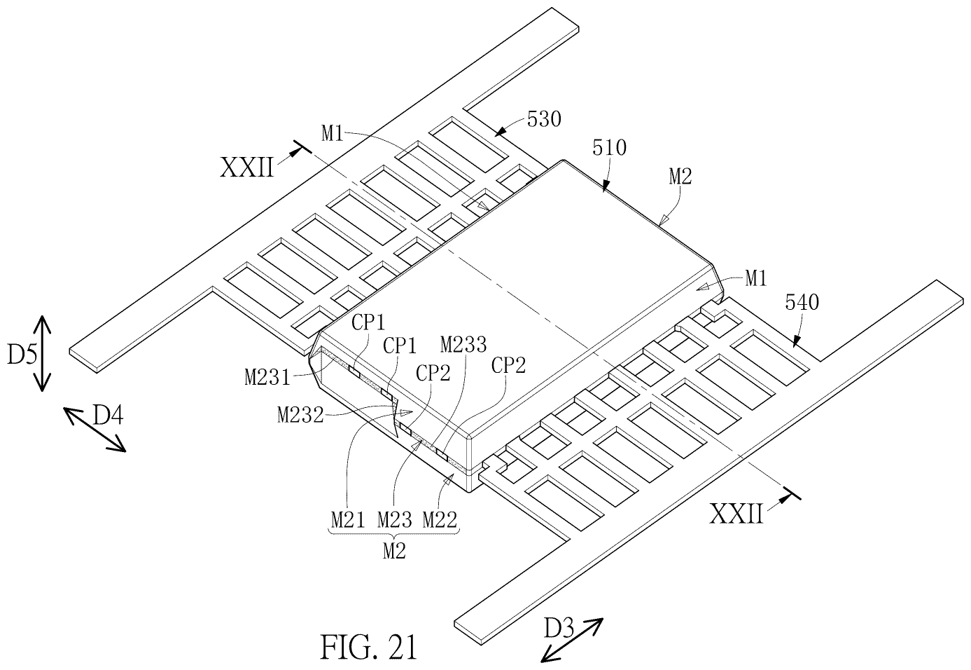

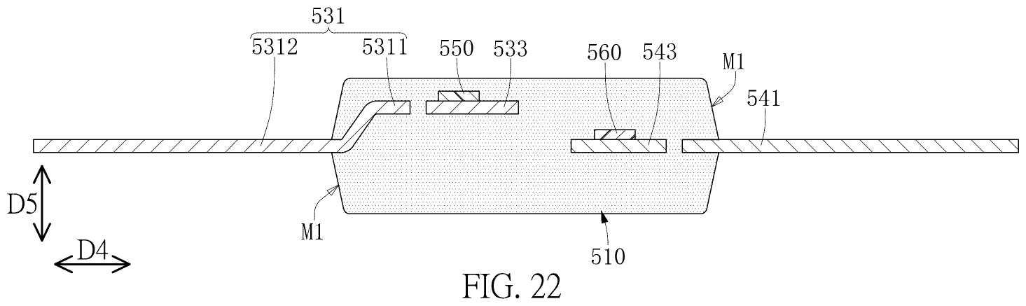

When the first package member 510 is viewed in a three-dimensional perspective, one of the two first sides M1 includes the two adjacent surfaces on a left direction of the first package member 510 in FIG. 22, and another one of the two first sides M1 includes the two adjacent surfaces on a right direction of the first package member 510 in FIG. 22. Additionally, one of the two second sides M2 includes the two adjacent surfaces on a front direction of the first package member 510 in FIG. 21, and another one of the two second sides M2 includes the two adjacent surfaces on a rear direction of the first package member 510 (not shown).

Naturally, the first package member 510 may also take other three-dimensional shapes. For example, in another embodiment of the present disclosure (not shown), the first package member 510 may be a rectangular cuboid. That is to say, the shape of the first package member 510 in the present disclosure is not limited thereto.

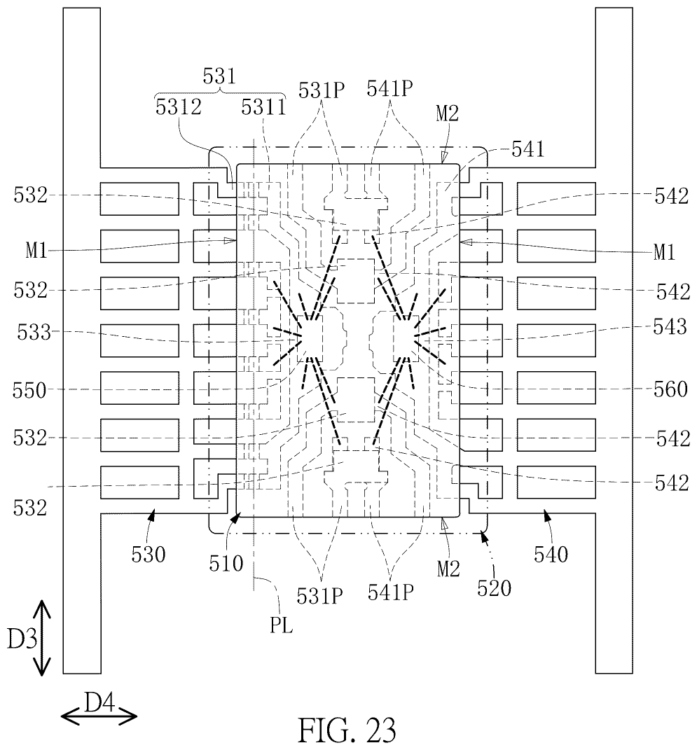

Referring to FIG. 23 and FIG. 24, the first package member 510 is covered by the second package member 520. In practice, the second package member 520 is molded onto the first package member 510 through secondary molding, so that the first package member 510 is completely encapsulated by the second package member 520.

Referring to FIG. 21 and FIG. 23, the first conductive component 530 and the second conductive component 540 are partially disposed in the first package member 510, so that a portion of the first conductive component 530 and a portion of the second conductive component 540 extend through the two first sides M1 and protrude outside the second package member 520. Another portion of the first conductive component 530 and another portion of the second conductive component 540 are flush with the second sides M2.

In other words, a portion of the first conductive component 530 and a portion of the second conductive component 540 along the width direction D4 penetrate the second package member 520 through the first package member 510 in the width direction D4, and extend out from the opposite sides of the second package member 520 along the width direction D4 (i.e., the two first sides M1) to be exposed outside the second package member 520.

Additionally, a portion of the first conductive component 530 and a portion of the second conductive component 540 along the length direction D3 are flush with the opposite side surfaces of the first package member 510 in the length direction D3 (i.e., the two second sides M2). In other words, the first conductive component 530 is not encapsulated by two end portions of the second package member 520 along the length direction D3.

More specifically, each of the two second sides M2 has a first region M21 and a second region M22 spaced apart from each other, and a middle region M23 that is located between the first region M21 and the second region M22. The positions of a portion of the first conductive component 530 (hereinafter referred to as a first flush section CP1) and a portion of the second conductive component 540 (hereinafter referred to as the second flush section CP2) flush with one of the two second sides M2 are both located in the middle region M23.

Preferably, a height position of the first flush section CP1 along a height direction D5, which is perpendicular to the length direction D3 and the width direction D4, may differ from a height position of the second flush section CP2 along the height direction D5.

Specifically, the middle region M23 in the present embodiment has a stepped shape and includes a first lateral portion M231, a vertical portion M232, and a second lateral portion M233, and two ends of the vertical portion M232 are connected to the first lateral portion M231 and the second lateral portion M233. The vertical portion M232 is perpendicular to both the first lateral portion M231 and the second lateral portion M233. The first flush section CP1 is located on the first lateral portion M231, and the second flush section CP2 is located on the second lateral portion M233.

It is worth noting that, in practice, the vertical portion M232 can serve as a glue channel for the first package member 510 during the packaging process.

For example, two molds (not shown) are designed to shape the encapsulating material to feature the characteristics of the first package member 510 in the present disclosure (e.g., the two second sides M2 and the two first sides M1), and the two molds are designed with a glue injection hole and a discharge hole corresponding to the two side regions at the vertical portion M232. During actual production, the first conductive component 530 and the second conductive component 540 are placed inside the two molds. Once combined, the two molds are filled with an encapsulating material through the glue injection hole, while the excess material is discharged through the discharge hole. When the encapsulating material solidifies, two side surfaces of the encapsulating material along the length direction are cut by a tool, so that exposed portions of the first conductive component 530 and the second conductive component 540 in the length direction are trimmed, and are flush with the two side surfaces of the encapsulating material in the length direction D3 (i.e., the first conductive component 530 and the second conductive component 540 shown in FIG. 20 are processed to become the first conductive component 530 and the second conductive component 540 as depicted in FIG. 21 and FIG. 23).

In practice, the tool can cut a portion of the encapsulating material (i.e., the first package member), so that a surface roughness of the middle region M23 of each of the two second sides M2 is greater than a surface roughness of each of the first region M21 and the second region M22 of each of the two second sides M2. Accordingly, when the first package member undergoes secondary encapsulation, a bonding strength between the first package member 510 and the second package member 520 can be increased.

To facilitate understanding of “the relationship between the first flush section CP1 and the second flush section CP2 at different height positions relative to the first package member 510 and the second package member 520,” a more detailed explanation of the first conductive component 530 and the second conductive component 540 is provided below.

Referring to FIG. 19 and FIG. 22, the first conductive component 530 has a predetermined configuration line PL, and a height position of a portion of the first conductive component 530 on one of two sides of the predetermined configuration line PL (e.g., a right side in FIG. 20) is either higher or lower than a height position of a portion on another one of the two sides of the predetermined configuration line PL (e.g., a left side in FIG. 20). In practice, the predetermined configuration line PL can be understood as a working position where a bending device performs the bending operation on the first conductive component 530. In other words, the first conductive component 530 is divided into two portions after being bent along the predetermined configuration line PL, the two portions are respectively located in two planes, and one of the two planes is higher than another one of the two planes.

More specifically, the first conductive component 530 includes a plurality of first leads 531, two first coupling plates 532, and a first placement pad 533 that are electrically connected to the first chip 550. The first leads 531, the two first coupling plates 532, and the first placement pad 533 are disposed in the first package member 510, and a portion of the first leads 531 is connected to the first placement pad 533. The ends of the first leads 531 further extend through the two first sides M1 and the second package member 520, so as to expose outside the second package member 520. That is to say, each of the first leads 531 extends roughly along the width direction D4.

Additionally, the first leads 531 are jointly intersected by the predetermined configuration line PL. Specifically, each of the first leads 531 includes a first medial segment 5311 and a first lateral segment 5312 that is connected to the first medial segment 5311. The predetermined configuration line PL passes between the first medial segment 5311 and the first lateral segment 5312, so that a height position of the first lateral segment 5312 along the height direction D5 to differ from a height position of the first medial segment 5311 along the height direction D5.

Moreover, the height positions of the two first coupling plates 532 and the first placement pad 533 along the height direction D5 are equal to the height position of the first medial segment 5311.

Referring to FIG. 19 and FIG. 22, a structure of the second conductive component 540 is generally similar to that of the first conductive component 530. That is, the second conductive component 540 includes a plurality of second leads 541, two second coupling plates 542, and a second placement pad 543 that are electrically connected to the second chip 560.

The second leads 541, the two second coupling plates 542, and the second placement pad 543 are disposed in the first package member 510, and a portion of the second leads 541 is connected to the second placement pad 543. Additionally, the ends of the second leads 541 further extend through the two first sides M1 and the second package member 520 along the width direction D4, so as to expose outside the second package member 520.

The difference between the second conductive component 540 and the first conductive component 530 is that the second conductive component 540 has not been processed by a bending device. Additionally, the height position of the second conductive component 540 along the height direction D5 is equal to the height position of each of the first lateral segments 5312 along the height direction D5. In other words, the height positions of the second leads 541, the two second coupling plates 542, and the second placement pad 543 are equal to the height position of each of the first lateral segments 5312. That is to say, the second conductive component 540 is a planar structure, but the present disclosure is not limited thereto. Accordingly, the capacitive coupling package structure 500 can meet the isolation distance requirement (i.e., greater than or equal to 400 micrometers), while also ensuring the consistency of the capacitance value and the electrical performance of the coupling capacitor.

For example, in another embodiment of the present disclosure (not shown), the height position of the second conductive component 540 along the height direction D5 can also be equal to the height position of each first medial segment 5311 along the height direction D5.

Additionally, it should be noted that the two first coupling plates 532 and the second coupling plates 542 are used to establish a capacitive coupling relationship for each of the first chip 550 and the second chip 560.

Specifically, as shown in FIG. 19 and FIG. 20, the first coupling plate 532 and the second coupling plate 542 are spaced apart from each other along the height direction D5. A projection of the first coupling plate 532 along the height direction D5 onto a bottom surface of the second package member 520 largely overlaps with a projection of the second coupling plate 542 along the height direction D5 onto the bottom surface of the second package member 520.

Accordingly, when the first coupling plate 532 and second coupling plate 542 adjacent to each other are close to each other but not in contact, the first coupling plate 532 and second coupling plate 542 adjacent to each other generate capacitance through the effect of the electric field.

Additionally, to avoid the impact of parasitic capacitances between the first coupling plate 532 and the second coupling plate 542, the first leads 531 connected to the first coupling plate 532 and the second leads 541 connected to the second coupling plate 542 can be arranged in a skewed configuration relative to the first coupling plate and second coupling plate.

Specifically, the first leads 531 connected to the first coupling plate 532 are each defined as a first coupling lead 531P, and the second leads 541 connected to the second coupling plate 542 are each defined as a second coupling lead 541P. A first predetermined angle θ1 is between the first coupling lead 531P and the first coupling plate 532, a second predetermined angle θ2 is between the second coupling lead 541P and the second coupling plate 542, and the first predetermined included angle θ1 and the second predetermined included angle θ2 are preferably greater than or equal to 10 degrees. The first coupling lead 531P and the second coupling lead 541P are located on different planes. In other words, the height positions of the first coupling leads 531P and the second coupling leads 541P along the height direction D5 are different.

Furthermore, in order to ensure that deformation can be reduced between each of the first coupling leads 531P and the first coupling plate 532 and between each of the second coupling leads 541P and the second coupling plate 542, a width of one of two ends of each of the first coupling leads 531P adjacent to the first coupling plate 532 may be designed to be greater than a width of another one of the two ends of each of the first coupling leads 531P away from the first coupling plate 532, and a width of one of two ends of each of the second coupling leads 541P adjacent to the second coupling plate 542 can also be designed to be greater than a width of one of two ends of each of the second coupling lead 541P away from the second coupling plate 542.

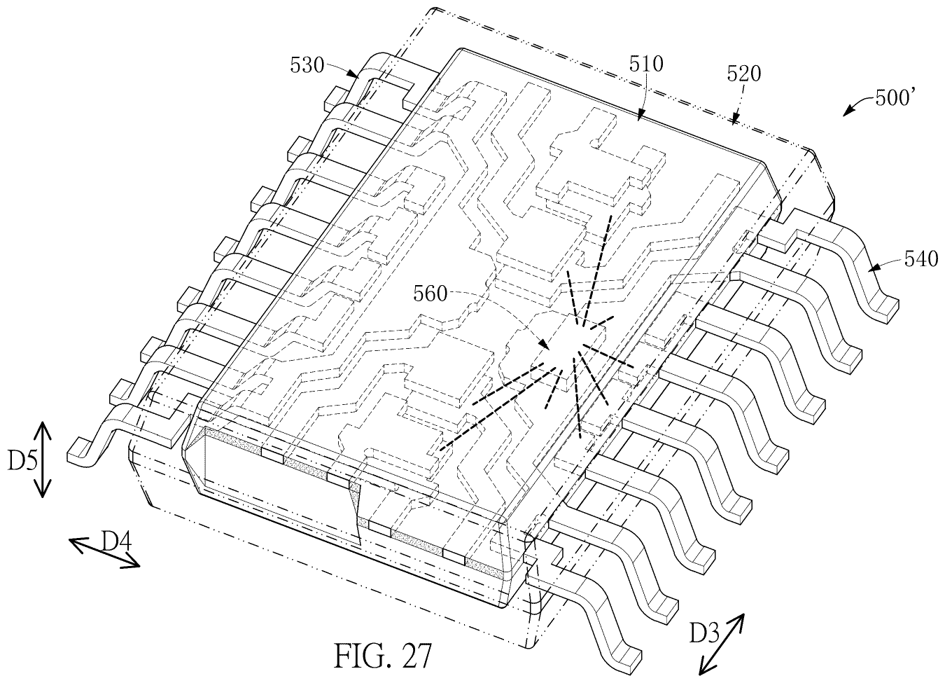

Additionally, it should be noted that the capacitive coupling package structure 500 in the present embodiment includes both the first chip 550 and the second chip 560, but one of the chips may be omitted depending on the situation (e.g., as shown in the capacitive coupling package structure 500′ in FIG. 27).

### Beneficial Effects of the Embodiment

In conclusion, in the capacitive coupling package structure provided by the present disclosure, by virtue of “the first conductive component and the second conductive component being disposed in the first package member,” and “a portion of the first conductive component and a portion of the second conductive component respectively extending through the two first sides to the outside of the second package member, and another portion of the first conductive component and another portion of the second conductive component being flush with the two second sides,” the capacitive coupling package structure can increase the isolation voltage.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A capacitive coupling package structure, comprising:
a first package member having two first sides and two second sides that are opposite to the two first sides and that are connected to the two first sides;
a second package member, wherein the first package member is covered by the second package member;
a first conductive component and a second conductive component disposed in the first package member, wherein a portion of the first conductive component and a portion of the second conductive component respectively extend through the two first sides to an outside of the second package member, and wherein another portion of the first conductive component and another portion of the second conductive component are flush with the two second sides; and
a first chip and a second chip, wherein the first chip is electrically coupled to the first conductive component, and the second chip is electrically coupled to the second conductive component, and wherein a capacitive coupling relationship is established by the first chip and the second chip through the first conductive component and the second conductive component.

2. The capacitive coupling package structure according to claim 1, wherein each of the two second sides has a first region and a second region spaced apart from each other, and a middle region that is located between the first region and the second region, and wherein the portion of the first conductive component flush with one of the two second sides and the portion of the second conductive component flush with one of the two second sides are located in the middle region.

3. The capacitive coupling package structure according to claim 2, wherein a surface roughness of the middle region of each of the two second sides is greater than a surface roughness of the first region and the second region of each of the two second sides.

4. The capacitive coupling package structure according to claim 2, wherein the middle region is in a stepped shape and includes a first lateral portion, a vertical portion, and a second lateral portion, and two ends of the vertical portion are connected to the first lateral portion and the second lateral portion, and wherein the portion of the first conductive component flush with one of the two second sides is located in the first lateral portion, and the portion of the second conductive component flush with one of the two second sides is located in the second lateral portion.

5. The capacitive coupling package structure according to claim 1, wherein the first conductive component has a predetermined configuration line, and a height position of a portion of the first conductive component located on one of two sides of the predetermined configuration line is higher or lower than a height position of a portion of the first conductive component located on another one of two sides of the predetermined configuration line.

6. The capacitive coupling package structure according to claim 5, wherein the first conductive component includes a plurality of first leads electrically coupled to the first chip, and two first coupling plates that are electrically coupled to the first chip, wherein the first leads are disposed in the first package member, and ends of the first leads pass through the two first sides and the second package member, and the ends of the first leads are exposed to the outside of the second package member; wherein the second conductive component includes a plurality of second leads electrically coupled to the second chip, and two second coupling plates that are electrically coupled to the second chip, and wherein a portion of the first leads connected to the two first coupling plates is defined as a first coupling lead, a portion of the second leads connected to the two second coupling plates is defined as a second coupling lead, and a height position of the first coupling lead is different from a height position of the second coupling lead.

7. The capacitive coupling package structure according to claim 5, wherein the first conductive component includes a plurality of first leads electrically coupled to the first chip, and each of the first leads includes a first medial segment and a first lateral segment connected to the first medial segment, and wherein the predetermined configuration line passes between the first medial segment and the first lateral segment, and a height position of the first lateral segment is different from a height position of the first medial segment.

8. The capacitive coupling package structure according to claim 7, wherein the second conductive component includes a plurality of second leads connected to the second chip, and the second leads are disposed in the first package member, wherein ends of the second leads pass through the two first sides and the second package member, and are exposed to the outside of the second package member, and wherein a height position of each of the second leads is equal to a height position of each of the first lateral segments.

9. The capacitive coupling package structure according to claim 7, wherein the first conductive component includes two first coupling plates electrically coupled to the first chip, and the second conductive component includes two second coupling plates electrically coupled to the second chip, wherein the two first coupling plates and the two second coupling plates are disposed in the first package member, ends of the two first coupling plates are flush with one of the two second sides, and ends of the two second coupling plates are flush with the another one of the two second sides, and wherein a height position of each of the two first coupling plates is equal to the height position of each of the first medial segments, and a height position of each of the two second coupling plates is equal to the height position of each of the first lateral segments.

10. The capacitive coupling package structure according to claim 7, wherein the first conductive component also includes a first placement pad, and the first chip is disposed on the first placement pad, wherein the second conductive component also includes a second placement pad, and the second chip is disposed on the second placement pad, and wherein a height position of the first placement pad is equal to a height position of each of the first medial segments, and a height position of the second placement pad is equal to a height position of each of the first lateral segments.

11. The capacitive coupling package structure according to claim 9, wherein a portion of the first leads is connected to the two first coupling plates and is defined as a first coupling lead, wherein a first predetermined angle is between the first coupling lead and the first coupling plate, wherein a portion of the second leads is connected to the two second coupling plates and is defined as a second coupling lead, and wherein a second predetermined angle is between the second coupling lead and the second coupling plate, and the first predetermined angle and the second predetermined angle are greater than or equal to 10 degrees.

12. The capacitive coupling package structure according to claim 9, wherein a portion of the first leads is connected to the two first coupling plates and is defined as a first coupling lead, a width of an end of the first coupling lead adjacent to the first coupling plate is greater than a width of an end of the first coupling lead away from the first coupling plate, and wherein a portion of the second leads is connected to the two second coupling plates and is defined as a second coupling lead, and a width of an end of the second coupling lead adjacent to the second coupling plate is greater than a width of an end of the second coupling lead away from the second coupling plate.
